(19) United States
(12) Patent Application Publication
(10) Pub. No.: US 2012/0227807 A1
(43) Pub. Date: Sep. 13, 2012

(54) ORGANIC PHOTOVOLTAIC CELL

(76) Inventors: Takehito Kato, Tochigi (JP); Toshihiro Ohnishi, Ibaraki (JP)

(21) Appl. No.: 13/502,892

(22) PCT Filed: Oct. 26, 2010
(86) PCT No.: PCT/JP2010/068945

§ 371 Date: Apr. 19, 2012

(30) Foreign Application Priority Data
Oct. 30, 2009 (JP) 2009-250767

(51) Int. Cl. H01L 31/0232; H01L 51/44

(52) U.S. Cl. 136/257; 136/263

(57) ABSTRACT

Provided is an organic photovoltaic cell having excellent photovoltaic conversion efficiency. An organic photovoltaic cell 100 comprises a first electrode 6, an active layer 4 capable of generating charges by incident light, a second electrode 2, and a wavelength conversion layer 9 capable of wavelength conversion of incident ultraviolet light into light having longer wavelength than that of the ultraviolet light and outputting the resulting light, in this order.

### TECHNICAL FIELD

The present invention relates to an organic photovoltaic cell.

### BACKGROUND ART

A photovoltaic cell is a cell that can convert light energy into electric energy and an example thereof is a solar cell. The solar cell typically includes a silicon solar cell. However, the silicon solar cell requires a high vacuum environment and a high pressure environment in the production process to increase production cost. On this account, an organic solar cell has been drawing attention because the production cost of the organic solar cell is lower than that of the silicon solar cell.

However, the organic solar cell tends to have lower photovoltaic conversion efficiency than that of the silicon solar cell. Furthermore, the organic solar cell uses an organic material, which is likely to deteriorate due to ultraviolet light (UV) and the like, and thus the organic solar cell tends to have shorter lifetime than that of the silicon solar cell. Hence, in order to improve the photovoltaic conversion efficiency and to elongate the lifetime of the organic solar cell, various techniques have been developed. For example, Patent Document 1 discloses an organic solar cell that includes an UV out film in order to block ultraviolet light.

### RELATED ART DOCUMENTS

### Patent Literature

Patent Document 1: JP 2007-67115 A

### SUMMARY

Blocking incident ultraviolet light by the UV cut film can suppress the deterioration of the organic material due to the ultraviolet light and elongate the lifetime of the organic solar cell. However, blocking ultraviolet light alone cannot improve the photovoltaic conversion efficiency of the organic solar cell; therefore, there is a demand for techniques that can improve the photovoltaic conversion efficiency. The aforementioned subject is also common to organic photovoltaic cells other than the organic solar cell.

In view of the above problems, the present invention provides an organic photovoltaic cell that has excellent photovoltaic conversion efficiency.

The inventors of the present invention have carried out intensive studies in order to solve the problems; as a result, they have found that it is possible to improve the photovoltaic conversion efficiency by providing a wavelength conversion layer in an organic photovoltaic cell and outputting light toward an active layer after wavelength-conversion of ultraviolet light input to the wavelength conversion layer into light having longer wavelength than that of the ultraviolet light, since energy of the ultraviolet light input to the organic photovoltaic cell can be used as available energy. In this manner, the present invention has been accomplished.

That is, the present invention is as follows.

[1] An organic photovoltaic cell comprising:

a first electrode;

an active layer capable of generating a charge by incident light;

a second electrode; and

a wavelength conversion layer capable of wavelength conversion of incident ultraviolet light into light having longer wavelength than that of the ultraviolet light and outputting the resulting light, in this order.

[2] The organic photovoltaic cell according to [1], further comprising an ultraviolet absorbing layer between the second electrode and the wavelength conversion layer.
[3] The organic photovoltaic cell according to [1] or [2], further comprising a functional layer between the active layer and the second electrode, the functional layer capable of transporting the charge generated in the active layer to the second electrode, and the functional layer comprising a material capable of absorbing ultraviolet light.
[4] The organic photovoltaic cell according to one of [1] to [3], wherein the wavelength conversion layer is formed through a process of applying a liquid composition comprising a wavelength conversion agent onto a layer to be in contact with the wavelength conversion layer in the organic photovoltaic cell, and the wavelength conversion agent is capable of wavelength conversion of incident ultraviolet light into light having longer wavelength than that of the ultraviolet light and outputting the resulting light.
[5] The organic photovoltaic cell according to one of [1] to [4], wherein the wavelength conversion layer comprises an inorganic phosphor.
[6] An organic photovoltaic cell comprising:

a first electrode;

an active layer capable of generating a charge by incident light;

a second electrode;

an ultraviolet absorbing layer; and

a wavelength conversion layer capable of wavelength conversion of incident ultraviolet light into light having longer wavelength than that of the ultraviolet light and outputting the resulting light, in this order,

wherein the ultraviolet absorbing layer is formed through a process of applying a liquid composition comprising a material capable of absorbing ultraviolet light onto a layer to be in contact with the ultraviolet absorbing layer in the organic photovoltaic cell.

### BRIEF DESCRIPTION OF DRAWINGS

FIG. 1 is a schematic cross-sectional view of an organic photovoltaic cell of a first embodiment of the present invention.

FIG. 2 is a schematic cross-sectional view of an organic photovoltaic cell of a second embodiment of the present invention.

FIG. 3 is a schematic cross-sectional view of an organic photovoltaic cell of a third embodiment of the present invention.

FIG. 4 is a schematic cross-sectional view of an organic photovoltaic cell of a fourth embodiment of the present invention.

### EXPLANATIONS OF LETTERS OR NUMERALS

1, 8 substrate
2 second electrode
3, 5, 11 functional layer
4 active layer
6 first electrode
7 sealer layer
9 wavelength conversion layer
10 ultraviolet absorbing layer
100, 200, 300, 400 organic photovoltaic cell

### DESCRIPTION OF EMBODIMENTS

Hereinafter, the present invention will be described in detail with reference to embodiments, exemplary substances, and the like, but the present invention is not limited thereto, and any changes and modifications may be made in the present invention without departing from the gist of the present invention. In the present invention, “ultraviolet light” refers to light having a wavelength of 400 nm or less.

[1. Outline]

The organic photovoltaic cell of the present invention comprises a first electrode, an active layer that can generate a charge by incident light, a second electrode, and a wavelength conversion layer that can wavelength-convert incident ultraviolet light into light having longer wavelength than that of the ultraviolet light and that can output the light, in this order. Hence, the layers are arranged in the order of the first electrode, the active layer, the second electrode, and the wavelength conversion layer. The organic photovoltaic cell of the present invention that comprises the wavelength conversion layer can wavelength-convert ultraviolet light that is input to the wavelength conversion layer into light having longer wavelength (for example, visible light, near infrared light, or infrared light) than that of the ultraviolet light. Thus, ultraviolet light energy contributing to the deterioration of the active layer can be used as light energy for generating a charge in the active layer. Therefore, the organic photovoltaic cell of the present invention can improve the photovoltaic conversion efficiency as much as the ultraviolet light energy subjected to wavelength-conversion.

The organic photovoltaic cell of the present invention may further have other layers in addition to the first electrode, the active layer, the second electrode, and the wavelength conversion layer. For example, the organic photovoltaic cell of the present invention may have an ultraviolet absorbing layer between the second electrode and the wavelength conversion layer, may have a functional layer between the first electrode and the active layer, and may have a functional layer between the active layer and the second electrode.

The organic photovoltaic cell of the present invention usually further comprises a substrate and, on the substrate, each layer (for example, the first electrode, the active layer, the second electrode, the wavelength conversion layer, the ultraviolet absorbing layer, and the functional layers) is stacked to constitute the organic photovoltaic cell of the present invention.

[2. Substrate]

The substrate is a member serving as a support of the organic photovoltaic cell of the present invention. The substrate usually employs a member that is not chemically changed during the formation of the electrode and the formation of an organic material layer. Examples of a material for the substrate may include glass, a plastic, a polymer film, and silicon. The materials for the substrate may be used alone or in combination of two or more of them at any ratio.

Usually, a transparent or translucent member is used as the substrate, but an opaque substrate may be used. However, when the opaque substrate is used, the electrode opposite to the opaque substrate (namely, either the first electrode or the second electrode which is the electrode more distant from the opaque substrate) is preferably transparent or translucent.

[3. First Electrode and Second Electrode]

Of the first electrode and the second electrode, one is an cathode and the other is a anode. At least one of the first electrode and the second electrode is preferably transparent or translucent so that light can readily enter the active layer placed between the first electrode and the second electrode. The organic photovoltaic cell of the present invention can usually convert wavelength of ultraviolet light included in light that is applied from the second electrode side to pass through the second electrode and enters the active layer. From the viewpoint of effective utilization of the advantages of the present invention, at least the second electrode is preferably transparent or translucent.

Examples of the transparent or translucent electrode may include an electrically conductive metal oxide film and a translucent metal thin film. Examples of a material for the transparent or translucent electrode may include: films formed using electrically conductive materials such as indium oxide, zinc oxide, tin oxide, complexes of them such as indium tin oxide (ITO), indium zinc oxide (IZO), and NESA; gold; platinum; silver; and copper. Among them, ITO, indium zinc oxide, and tin oxide are preferred.

As the material for the transparent or translucent electrode, an organic material may also be used. Examples of the organic material usable as the material for the electrode may include electrically conductive polymers such as polyaniline, a derivative thereof, polythiophene, and a derivative thereof.

Examples of a material for the opaque electrode may include a metal and an electrically conductive polymer. Specific examples of the material may include: metals such as lithium, sodium, potassium, rubidium, cesium, magnesium, calcium, strontium, barium, aluminum, scandium, vanadium, zinc, yttrium, indium, cerium, samarium, europium, terbium, and ytterbium; an alloy of two or more of the metals; an alloy of one or more of the metals and one or more of metals selected from a group consisting of gold, silver, platinum, copper, manganese, titanium, cobalt, nickel, tungsten, and tin; graphite; a graphite intercalation compound; polyaniline and a derivative thereof; and polythiophene and a derivative thereof. Specific examples of the alloy may include a magnesium-silver alloy, a magnesium-indium alloy, a magnesium-aluminum alloy, an indium-silver alloy, a lithium-aluminum alloy, a lithium-magnesium alloy, a lithium-indium alloy, and a calcium-aluminum alloy.

The materials for the electrode may be used alone or in combination of two or more of them at any ratio.

Each of the first electrode and the second electrode has a varied thickness depending on the material type of the electrode. The thickness is preferably 500 nm or smaller and more preferably 200 nm or smaller in order to increase transmittance of light and to suppress electric resistance. The thickness has no lower limit but is usually 10 nm or larger.

Examples of the formation method of the first electrode and the second electrode may include a vacuum deposition method, a sputtering method, an ion plating method, and a plating method. For the formation of the first electrode and the second electrode from, for example, an electrically conductive polymer, a coating method may be employed.

[4. Active Layer]

The active layer is a layer capable of generating a charge by incident light and usually comprises a p-type semiconductor that is an electron-donating compound and an n-type semiconductor that is an electron-accepting compound. The organic photovoltaic cell of the present invention uses organic compounds as at least one of the p-type semiconductor and the n-type semiconductor, usually as both semiconductors, and hence is called the “organic” photovoltaic cell. The p-type semiconductor and the n-type semiconductor are relatively determined by the energy level of each energy state of the semiconductors.

In the active layer, the charge is supposed to be generated in the following manner. When light energy input to the active layer is absorbed in one or both of the n-type semiconductor and the p-type semiconductor, an exciton comprising an electron and a hole bonded to each other is formed. The formed exciton is transferred to reach to a heterojunction interface where the n-type semiconductor is contact with the p-type semiconductor. Then, the electron and hole are separated due to corresponding differences of the HOMO (highest occupied molecular orbital) energies and the LUMO (lowest unoccupied molecular orbital) energies at the heterojunction interface, thus generating charges (electron and hole) that can independently move. The generated charges are transferred to the corresponding electrodes to be able to be extracted from the organic photovoltaic cell of the present invention as electric energy (current) to the exterior.

The active layer may have a single layer structure comprising one layer alone or may have a stacked structure comprising two or more layers as long as the active layer can generate a charge by incident light. Examples of the layer composition of the active layer include the following layer compositions. However, the layer composition of the active layer is not limited to the examples.

Layer composition (i): the active layer having a stacked structure comprising a layer comprising the p-type semiconductor and a layer comprising the n-type semiconductor.

Layer composition (ii): the active layer having a single layer structure comprising the p-type semiconductor and the n-type semiconductor.

Layer composition (iii): the active layer having a stacked structure comprising a layer comprising the p-type semiconductor, a layer comprising the p-type semiconductor and the n-type semiconductor, and a layer comprising the n-type semiconductor.

Examples of the p-type semiconductor may include a pyrazoline derivative, an arylamine derivative, a stilbene derivative, a triphenyldiamine derivative, oligothiophene and a derivative thereof, polyvinylcarbazole and a derivative thereof, polysilane and a derivative thereof, a polysiloxane derivative having an aromatic amine on a side chain or the main chain, polyaniline and a derivative thereof, polythiophene and a derivative thereof, polypyrrole and a derivative thereof, poly(phenylene vinylene) and a derivative thereof, and poly(thienylene vinylene) and a derivative thereof.

An organic macromolecular compound having a structural unit represented by the following structural formula (1) is preferred as the p-type semiconductor.

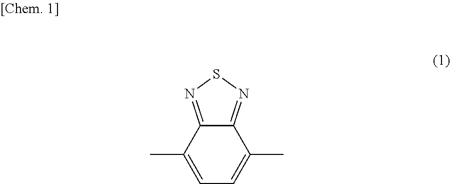

The organic macromolecular compound is more preferably a copolymer of the compound having the structural unit represented by the structural formula (1) and a compound represented by the following structural formula (2).

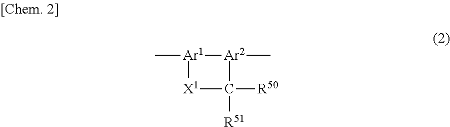

[In Formula (2), Ar¹ and Ar² are the same as or different from each other and represent a trivalent heterocyclic group. X¹ represents —O—, —S—, —C(═O)—, —S(═O)—, —SO₂—, —Si(R³) (R⁴)—, —N(R⁵)—, —B(R⁶)—, —P(R⁷)—, or —P(═O) (R⁸)—. R³, R⁴, R⁵, R⁶, R⁷, and R⁸ are the same as or different from each other and represent a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an amino group, a substituted amino group, a substituted silyl group, a substituted silyloxy group, a substituted silylthio group, a substituted silylamino group, a monovalent heterocyclic group, a heterocyclyloxy group, heterocyclylthio group, an arylalkenyl group, an arylalkynyl group, a carboxyl group, or a cyano group. R⁵⁰ represents a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group, or a cyano group. R⁵¹ represents an alkyl group having six or more carbon atoms, an alkyloxy group having six or more carbon atoms, an alkylthio group having six or more carbon atoms, an aryl group having six or more carbon atoms, an aryloxy group having six or more carbon atoms, an arylthio group having six or more carbon atoms, an arylalkyl group having seven or more carbon atoms, an arylalkyloxy group having seven or more carbon atoms, an arylalkylthio group having seven or more carbon atoms, an acyl group having six or more carbon atoms, or an acyloxy group having six or more carbon atoms. X¹ and Ar² are bonded to vicinal positions of the heterocyclic ring comprised in Ar¹, and C(R⁵⁰)(R⁵¹) and Ar¹ are bonded to vicinal positions of the heterocyclic ring comprised in Ar²]

The p-type semiconductors may be used alone or in combination of two or more of them at any ratio.

Examples of the n-type semiconductor may include an oxadiazole derivative, anthraquinodimethane and a derivative thereof, benzoquinone and a derivative thereof, naphthoquinone and a derivative thereof, anthraquinone and a derivative thereof, tetracyanoanthraquinodimethane and a derivative thereof, a fluorenone derivative, diphenyldicyanoethylene and a derivative thereof, a diphenoquinone derivative, metal complexes of 8-hydroxyquinoline and a derivative thereof, polyquinoline and a derivative thereof, polyquinoxaline and a derivative thereof, polyfluorene and a derivative thereof, fullerenes such as C₆₀ and a derivative thereof, a phenanthrene derivative such as bathocuproine, a metal oxide such as titanium dioxide, and a carbon nanotube. Among them, titanium dioxide, a carbon nanotube, a fullerene, and a fullerene derivative are preferred, and a fullerene and a fullerene derivative are especially preferred.

Examples of the fullerene may include C₆₀ fullerene, C₇₀ fullerene, C₇₆ fullerene, C₇₈ fullerene, and C₈₄ fullerene.

Examples of the fullerene derivative may include derivatives of C₆₀, C₇₀, C₇₆, C₇₈, and C₈₄. Specific examples of the fullerene derivative may include compounds having the following structures.

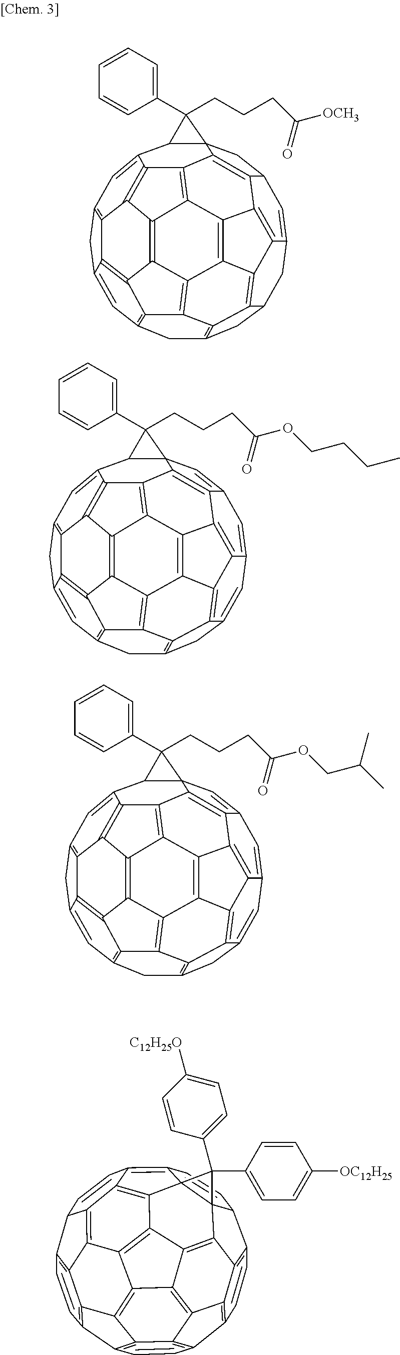

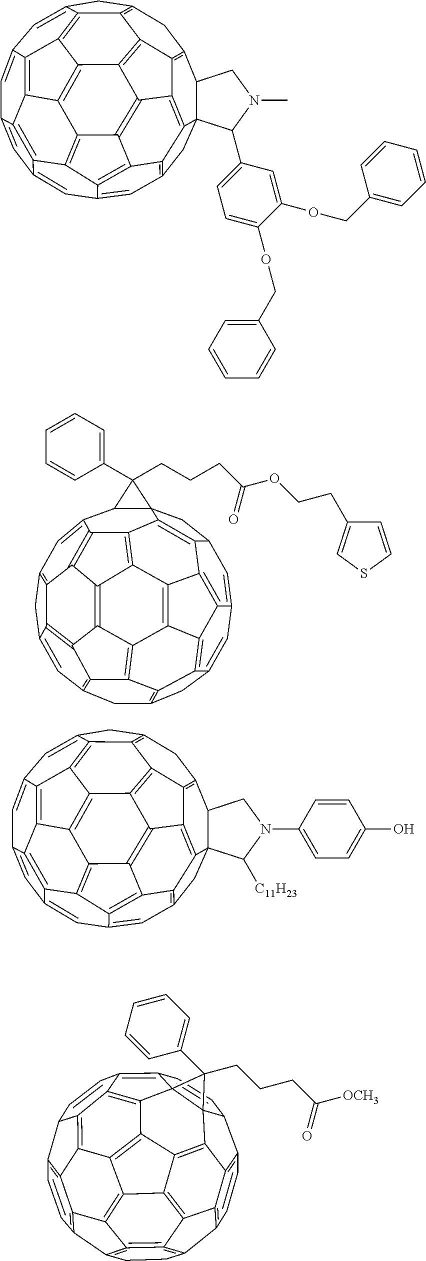

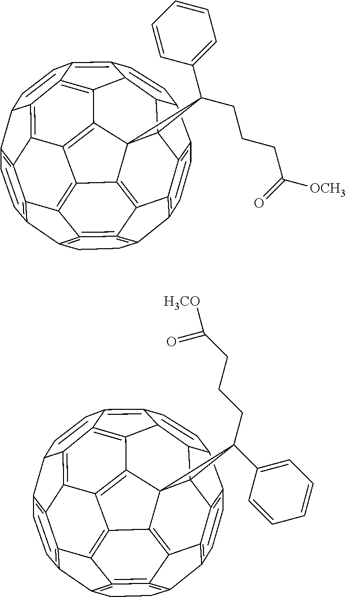

Other examples of the fullerene derivative may include [6,6]-phenyl C₆₁ butyric acid methyl ester (C60PCBM), [6,6]-phenyl C₇₁ butyric acid methyl ester (C70PCBM), [6,6]-phenyl C₈₅ butyric acid methyl ester (C84PCBM), and [6,6]-thienyl C₆₁ butyric acid methyl ester.

The n-type semiconductors may be used alone or in combination of two or more of them at any ratio.

The active layer may comprise the p-type semiconductor and the n-type semiconductor at any ratio as long as the effect of the present invention is not impaired. For example, in a layer comprising both of the p-type semiconductor and the n-type semiconductor in the layer compositions (i) and (iii), the n-type semiconductor is preferably comprised in an amount of 10 parts by weight or more and more preferably 20 parts by weight or more, and is preferably comprised in an amount of 1,000 parts by weight or less and more preferably 500 parts by weight or less, with respect to 100 parts by weight of the p-type semiconductor.

The active layer usually has a thickness of 1 nm or larger, preferably 2 nm or larger, more preferably 5 nm or larger, and particularly preferably 20 nm or larger, and usually has a thickness of 100 μm or smaller, preferably 1,000 nm or smaller, more preferably 500 nm or smaller, and particularly preferably 200 nm or smaller.

The active layer may be formed by any method. Examples of the method may include a film formation method from a liquid composition comprising a material (for example, one or both of the p-type semiconductor and the n-type semiconductor) for the active layer; and a film formation method by a gas phase film formation method such as a physical vapor deposition method (PVD method) including a vacuum deposition method and a chemical vapor deposition method (CVD method). Among them, the film formation method from a liquid composition is preferred because a film is readily formed to reduce the cost.

In the film formation method from a liquid composition, a liquid composition is prepared, the liquid composition is applied onto a desired area to form a film as the active layer.

The liquid composition usually comprises a material for the active layer and a solvent. When the solvent is contained, the liquid composition may be a dispersion liquid dispersing the material for the active layer in the solvent, but is preferably a solution dissolving the material for the active layer in the solvent. Hence, the solvent to be used is preferably a solvent that can dissolve the material for the active layer. Examples of the solvent may include: unsaturated hydrocarbon solvents such as toluene, xylene, mesitylene, tetralin, decalin, bicyclohexyl, n-butylbenzene, sec-butylbenzene, and tert-butylbenzene; halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, and bromocyclohexane; halogenated unsaturated hydrocarbon solvents such as chlorobenzene, dichlorobenzene, and trichlorobenzene; and ether solvents such as tetrahydrofuran and tetrahydropyran. The solvents may be used alone or in combination of two or more of them at any ratio.

Each concentration of the p-type semiconductor and the n-type semiconductor in the liquid composition is usually adjusted to 0.1% by weight or more with respect to a solvent.

Examples of the film formation method of the liquid composition may include coating methods such as a spin coating method, a casting method, a micro-gravure coating method, a gravure coating method, a bar coating method, a roll coating method, a wire bar coating method, a dip coating method, a spray coating method, a screen printing method, a gravure printing method, a flexographic printing method, an offset printing method, an inkjet printing method, a dispenser printing method, a nozzle coating method, and a capillary coating method. Among them, a spin coating method, a flexographic printing method, a gravure printing method, an inkjet printing method, and a dispenser printing method are preferred.

After the film formation of the liquid composition, as necessary, a process such as a process of drying the formed film to remove the solvent is performed, and consequently the active layer is obtained.

For an active layer having a stacked structure comprising two or more layers, for example, each layer constituting the active layer may be sequentially stacked by the aforementioned method.

### [5. Wavelength Conversion Layer]

The wavelength conversion layer is a layer that can perform wavelength-conversion of incident ultraviolet light into light having longer wavelength than that of the ultraviolet light and that can output the light. Thus, at least some of ultraviolet light that is included in light applied to the organic photovoltaic cell of the present invention and that is input to the wavelength conversion layer is subjected to wavelength-conversion into light having longer wavelength than that of the ultraviolet light in the wavelength conversion layer, and is output from the wavelength conversion layer to the exterior. At least some of the light that is output from the wavelength conversion layer and that has longer wavelength than that of the ultraviolet light is input to the active layer through the second electrode, and is used as light energy for charge generation in the active layer. As described above, the arrangement of the wavelength conversion layer can generally reduce the energy amount of the ultraviolet light that is input to the active layer, and can generally increase the energy amount of the light that is input to the active layer and that is available for the charge generation. Therefore, the organic photovoltaic cell of the present invention can suppress the deterioration of the active layer due to the ultraviolet light to elongate the lifetime of the organic photovoltaic cell, as well as can increase the charge generation amount in the active layer to improve the photovoltaic conversion efficiency.

The output light that has been subjected to wavelength-conversion from the absorbed ultraviolet light may be visible light, near infrared light, or infrared light, for example. The wavelength conversion layer that outputs visible light is preferred in order to increase the photovoltaic conversion efficiency.

In order to achieve the aforementioned functions, the wavelength conversion layer contains a wavelength conversion agent. The wavelength conversion agent is a material that can perform wavelength-conversion of incident ultraviolet light into light having longer wavelength than that of the ultraviolet light and can output the light. Usually, ultraviolet light input to the wavelength conversion agent is adsorbed into the wavelength conversion agent, and then light having longer wavelength than that of the absorbed ultraviolet light is output from the wavelength conversion agent. The wavelength conversion agents may be used alone or in combination of two or more of them at any ratio.

Examples of the wavelength conversion agent may include a phosphor. The phosphor is usually a material that can absorb excitation light to emit fluorescence having longer wavelength than that of the excitation light. Hence, for the phosphor used as the wavelength conversion agent, a phosphor capable of absorbing ultraviolet light as the excitation light and capable of emitting fluorescence having such wavelength available for the charge generation in the active layer may be used.

As the phosphor, an organic phosphor may be used, and an inorganic phosphor may be used. Examples of the organic phosphor may include a rare earth complex. The rare earth complex is a phosphor excellent in fluorescent characteristics, and specific examples may include a [Tb(bpy)₂]Cl₃ complex, an [Eu(phen)₂]Cl₃ complex, and a [Tb(terpy)₂]Cl₃ complex. Here, “bpy” represents 2,2-bipyridine, “phen” represents 1,10-phenanthroline, and “terpy” represents 2,2′:6′,2″-terpyridine. Examples of the inorganic phosphor may include MgF₂:Eu²⁺ (an absorption wavelength of 300 nm to 400 nm, a fluorescence wavelength of 400 nm to 550 nm), 1.29(Ba, Ca)O—6Al₂O₃:Eu²⁺ (an absorption wavelength of 200 nm to 400 nm, a fluorescence wavelength of 400 nm to 600 nm), BaAl₂O₄:Eu²⁺ (an absorption wavelength of 200 nm to 400 nm, a fluorescence wavelength of 400 nm to 600 nm), and Y₃Al₅O₁₂:Ce³⁺ (an absorption wavelength of 250 nm to 450 nm, a fluorescence wavelength of 500 nm to 700 nm). Among the phosphors, the inorganic phosphors are preferably used.

As necessary, the wavelength conversion layer may comprise a binder in order to hold the wavelength conversion agent. A preferred binder is a material that can hold the wavelength conversion agent in the wavelength conversion layer without significantly impairing the effect of the present invention, and a resin is usually used. Examples of the resin usable as the binder may include a polyester resin, an acrylic resin, an epoxy resin, and a fluorine resin. The binders may be used alone or in combination of two or more of them at any ratio.

The binder is usually used in an amount of 3 parts by weight or more, preferably 5 parts by weight or more, and more preferably 10 parts by weight or more, and is usually used in an amount of 80 parts by weight or less, preferably 50 parts by weight or less, and more preferably 30 parts by weight or less, with respect to 100 parts by weight of the wavelength conversion agent. The wavelength conversion layer using the binder in an excessively small amount may not stably hold the wavelength conversion agent, while the wavelength conversion layer using the binder in an excessively large amount may not sufficiently convert wavelength of ultraviolet light.

The wavelength conversion layer may contain other components in addition to the wavelength conversion agent and the binder as long as the effect of the present invention is not significantly impaired. Examples of the component may include additives such as a filler and an antioxidant.

The other components may be used alone or in combination of two or more of them at any ratio.

The wavelength conversion layer usually has a thickness of 1 μm or larger, preferably 10 μm or larger, and more preferably 100 μm or larger, and usually has a thickness of 10,000 μm or smaller, preferably 5,000 μm or smaller, and more preferably 3,000 μm or smaller. The wavelength conversion layer having an excessively small thickness may insufficiently convert wavelength of the ultraviolet light, while the wavelength conversion layer having an excessively large thickness may excessively increase the thickness of the organic photovoltaic cell.

The organic photovoltaic cell of the present invention may comprise one wavelength conversion layer and may comprise two or more layers.

The wavelength conversion layer is preferably formed thorough a process of applying a liquid composition comprising the wavelength conversion agent onto a predetermined area because the layer is readily formed to reduce the cost. The method for forming the wavelength conversion layer from the liquid composition will be described below.

The liquid composition for forming the wavelength conversion layer usually comprises a material, such as the wavelength conversion agent and the binder comprised as necessary, for the wavelength conversion layer and a solvent. When the solvent is comprised, the liquid composition may be a dispersion liquid dispersing the material for the wavelength conversion layer in the solvent and may be a solution dissolving the material for the wavelength conversion layer in the solvent.

Examples of the solvent contained in the liquid composition for forming the wavelength conversion layer may include solvents similar to the solvents contained in the liquid composition for forming the active layer. The solvents may be used alone or in combination of two or more of them at any ratio.

In the liquid composition, the solvent is usually contained in an amount of 10 parts by weight or more, preferably 50 parts by weight or more, and more preferably 100 parts by weight or more, and is usually contained in an amount of 100,000 parts by weight or less, preferably 10,000 parts by weight or less, and more preferably 5,000 parts by weight or less, with respect to 100 parts by weight of the wavelength conversion agent.

After the preparation of the liquid composition for forming the wavelength conversion layer, the liquid composition is applied onto a predetermined area where the wavelength conversion layer is intended to be formed. Usually, the liquid composition is applied onto a layer (usually, the second electrode or the ultraviolet absorbing layer) to be in contact with the wavelength conversion layer in the organic photovoltaic cell of the present invention. Examples of the coating method of the liquid composition may include coating methods similar to the coating methods of the liquid composition for forming the active layer.

The liquid composition for forming the wavelength conversion layer is applied to form a film comprising the wavelength conversion agent. Thus, after the application of the liquid composition, as necessary, a process such as a process of drying the formed film to remove the solvent is performed, and consequently the wavelength conversion layer is obtained.

[6. Ultraviolet Absorbing Layer]

The organic photovoltaic cell of the present invention preferably comprises an ultraviolet absorbing layer that can block ultraviolet light between the second electrode and the wavelength conversion layer. That is, the organic photovoltaic cell of the present invention preferably comprises the first electrode, the active layer, the second electrode, the ultraviolet absorbing layer, and the wavelength conversion layer, in this order.

The wavelength conversion layer usually does not convert wavelength of all ultraviolet light that is input to the organic photovoltaic cell of the present invention, but converts wavelength of some of the input ultraviolet light. Thus, when a special means is not provided, ultraviolet light that is not wavelength-converted in the wavelength conversion layer passes through the wavelength conversion layer to be input to the second electrode and the active layer. In contrast, when the ultraviolet absorbing layer is provided between the second electrode and the wavelength conversion layer, the ultraviolet light that is not wavelength-converted in the wavelength conversion layer can be prevented to be input to the second electrode and the active layer, and consequently the deterioration of the second electrode and the active layer due to the ultraviolet light can be more stably suppressed.

The ultraviolet absorbing layer usually comprises an ultraviolet absorber that is a material capable of absorbing ultraviolet light. As the ultraviolet absorber, an organic material may be used and an inorganic material may be used.

Among the ultraviolet absorbers, examples of the organic material may include benzophenone ultraviolet absorbers, benzotriazole ultraviolet absorbers, triazine ultraviolet absorbers, and phenyl salicylate ultraviolet absorbers. Among them, preferred examples specifically may include 2,4-dihydroxy-benzophenone, 2-hydroxy-4-methoxybenzophenone, 4-dodecyloxy-2-hydroxybenzophenone, 2-hydroxy-4-methoxy-5-sulfobenzophenone, 2-(2′-hydroxy-5-methylphenyl)benzotriazole, 2-(2′-hydroxy-3′,5′-di-tert-butylphenyl)benzotriazole, phenyl salicylate, p-octylphenyl salicylate, and p-tert-butylphenyl salicylate.

Among the ultraviolet absorbers, examples of the inorganic material may include titanium dioxide and zinc oxide.

The ultraviolet absorbers may be used alone or in combination of two or more of them at any ratio.

As necessary, the ultraviolet absorbing layer may comprise a binder in order to hold the ultraviolet absorber. A preferred binder is a material that can hold the ultraviolet absorber in the ultraviolet absorbing layer without significantly impairing the effect of the present invention, and a resin is usually used. Examples of the resin usable as the binder may include resins similar to the resins used as the binder in the wavelength conversion layer. The binders may be used alone or in combination of two or more of them at any ratio.

The binder is usually used in an amount of 3 parts by weight or more, preferably 5 parts by weight or more, and more preferably 10 parts by weight or more, and is usually used in an amount of 80 parts by weight or less, preferably 50 parts by weight or less, and more preferably 30 parts by weight or less, with respect to 100 parts by weight of the ultraviolet absorber. The ultraviolet absorbing layer using the binder in an excessively small amount may unstably hold the ultraviolet absorber, while the ultraviolet absorbing layer using the binder in an excessively large amount may insufficiently block ultraviolet light.

The ultraviolet absorbing layer may contain other components in addition to the ultraviolet absorber and the binder as long as the effect of the present invention is not significantly impaired. Examples of the other component may include components similar to the other components that may be contained in the wavelength conversion layer.

The other components may be used alone or in combination of two or more of them at any ratio.

The ultraviolet absorbing layer usually has a thickness of 1 μm or larger, preferably 10 μm or larger, and more preferably 100 μm or larger, and usually has a thickness of 10,000 μm or smaller, preferably 5,000 μm or smaller, and more preferably 3,000 μm or smaller. The ultraviolet absorbing layer having an excessively small thickness may insufficiently block ultraviolet light, while the ultraviolet absorbing layer having an excessively large thickness may excessively increase the thickness of the organic photovoltaic cell.

The organic photovoltaic cell of the present invention may comprise one ultraviolet absorbing layer and may comprise two or more layers.

The ultraviolet absorbing layer is preferably formed thorough a process of applying a liquid composition containing the ultraviolet absorber onto a predetermined area because the layer is readily formed to reduce the cost. The method for forming the ultraviolet absorbing layer from the liquid composition will be described below.

The liquid composition for forming the ultraviolet absorbing layer usually contains materials for the ultraviolet absorbing layer, such as the ultraviolet absorber and the binder contained as necessary, and a solvent. When the solvent is contained, the liquid composition may be a dispersion liquid dispersing the materials for the ultraviolet absorbing layer in the solvent and may be a solution dissolving the materials for the ultraviolet absorbing layer in the solvent.

Examples of the solvent contained in the liquid composition for forming the ultraviolet absorbing layer may include solvents similar to the solvents contained in the liquid composition for forming the active layer. The solvents may be used alone or in combination of two or more of them at any ratio.

In the liquid composition, the solvent is usually contained in an amount of 10 parts by weight or more, preferably 50 parts by weight or more, and more preferably 100 parts by weight or more, and is usually contained in an amount of 100,000 parts by weight or less, preferably 10,000 parts by weight or less, and more preferably 5,000 parts by weight or less, with respect of 100 parts by weight of the ultraviolet absorber.

After the preparation of the liquid composition for forming the ultraviolet absorbing layer, the liquid composition is applied onto a predetermined area where the ultraviolet absorbing layer is intended to be formed.

Usually, the liquid composition is applied onto a layer (usually, the second electrode or the wavelength conversion layer) to be in contact with the ultraviolet absorbing layer in the organic photovoltaic cell of the present invention. Examples of the coating method of the liquid composition may include coating methods similar to the coating methods of the liquid composition for forming the active layer.

The liquid composition for forming the ultraviolet absorbing layer is applied to form a film comprising the ultraviolet absorber. Thus, after the application of the liquid composition, as necessary, a process such as a process of drying the formed film to remove the solvent is performed, and consequently the ultraviolet absorbing layer is obtained.

[7. Functional Layer]

The organic photovoltaic cell of the present invention may comprise functional layers between the first electrode and the active layer and between the second electrode and the active layer. The functional layer is a layer that can transport the charge generated in the active layer to the electrode. The functional layer between the first electrode and the active layer can transport the charge generated in the active layer to the first electrode, while the functional layer between the second electrode and the active layer can transport the charge generated in the active layer to the second electrode. The functional layer may be provided either between the first electrode and the active layer or between the second electrode and the active layer, and the functional layers may be provided both between the first electrode and the active layer and between the second electrode and the active layer.

The functional layer provided between the active layer and an cathode can transport a hole generated in the active layer to the cathode, and is also called a hole transport layer or an electron block layer. Meanwhile, the functional layer provided between the active layer and a anode can transport an electron generated in the active layer to the anode, and is also called a electron transport layer or a hole block layer. The effective photovoltaic cell of the present invention that comprises the functional layers can increase extraction efficiency of the hole generated in the active layer to the cathode, can increase extraction efficiency of the electron generated in the active layer to the anode, can suppress transfer of the hole generated in the active layer to the anode, and can suppress transfer of the electron generated in the active layer to the cathode. Consequently, the photovoltaic conversion efficiency can be improved.

The functional layer may comprise a material that can transport the charge generated in the active layer. Specifically, the functional layer between the active layer and the cathode preferably comprises a material that can transport the hole and that can suppress the transfer of the electron to the functional layer. The functional layer between the active layer and the anode preferably comprises a material that can transport the electron and that can suppress the transfer of the hole to the functional layer.

Examples of the material for the functional layer may include: halides and oxides of an alkali metal or an alkaline earth metal, such as lithium fluoride; inorganic semiconductors such as titanium dioxide; bathocuproine, bathophenanthroline and a derivative thereof; a triazole compound; a tris(8-hydroxyquinolinate) aluminum complex; a bis(4-methyl-8-quinolinate) aluminum complex; an oxadiazole compound; a distyrylarylene derivative; a silole compound; a 2,2′,2″-(1,3,5-benzenetolyl)-tris-[1-phenyl-1H-benzimidazole] (TPBI) phthalocyanine derivative; a naphthalocyanine derivative; a porphyrin derivative; aromatic diamine compounds such as N,N′-bis(3-methylphenyl)-(1,1′-biphenyl)-4,4′-diamine (TPD) and 4,4′-bis[N-(naphthyl)-N-phenyl-amino]biphenyl (α-NPD); oxazole; oxadiazole; triazole; imidazole; imidazolone; a stilbene derivative; a pyrazoline derivative; tetrahydroimidazole; poly(aryl alkane); butadiene; 4,4′,4″-tris(N-(3-methylphenyl)-N-phenylamino)triphenylamine (m-MTDATA); polyvinylcarbazole; polysilane; and poly(3,4-ethylenedioxidethiophene) (PEDOT). The materials may be used alone or in combination of two or more of them at any ratio.

In the organic photovoltaic cell of the present invention, the functional layer between the second electrode and the active layer preferably comprises an ultraviolet absorber. The functional layer that contains the ultraviolet absorber and that is placed between the second electrode and the active layer can absorb ultraviolet light that cannot be sufficiently wavelength-converted or blocked in the wavelength conversion layer and the ultraviolet absorbing layer, thus reducing the amount of ultraviolet light that is input to the active layer.

The ultraviolet absorber comprised in the functional layer preferably has a function of transporting a charge, and an inorganic material is preferred. Preferred examples of the ultraviolet absorber that meets the condition may include titanium dioxide and zinc oxide. In particular, titanium dioxide is an excellent material because titanium dioxide itself can be used as the material for the functional layer as well as can be used as the ultraviolet absorber.

The functional layer between the second electrode and the active layer usually comprises the ultraviolet absorber at a ratio of 25% by weight or more, preferably 50% by weight or more, and more preferably 75% by weight or more in order to block a sufficient amount of ultraviolet light. The upper limit is 100% because an ultraviolet absorber such as titanium dioxide that can transport a charge may be used.

The functional layer may contain other components in addition to the aforementioned materials as long as the effect of the present invention is not significantly impaired.

The other components may be used alone or in combination of two or more of them at any ratio.

The functional layer usually has a thickness of 0.01 nm or larger, preferably 0.1 nm or larger, and more preferably 1 nm or larger, and usually has a thickness of 1,000 nm or smaller, preferably 500 nm or smaller, and more preferably 100 nm or smaller. The functional layer having an excessively small thickness may insufficiently exert the functions of the functional layer, while the functional layer having an excessively large thickness may excessively increase the thickness of the organic photovoltaic cell.

The functional layer may be formed, for example, by a gas phase film formation method, but is preferably formed through a process of applying a liquid composition comprising the material for the functional layer onto a predetermined area because the layer is readily formed to reduce the cost. The method for forming the functional layer from the liquid composition will be described below.

The liquid composition for forming the functional layer usually comprises a material for the functional layer and a solvent. When the solvent is contained, the liquid composition may be a dispersion liquid dispersing the material for the functional layer in the solvent and may be a solution dissolving the material for the functional layer in the solvent.

Examples of the solvent contained in the liquid composition for forming the functional layer may include solvents similar to the solvents contained in the liquid composition for forming the active layer. The solvents may be used alone or in combination of two or more of them at any ratio.

In the liquid composition, the solvent is usually comprised in an amount of 10 parts by weight or more, preferably 50 parts by weight or more, and more preferably 100 parts by weight or more, and is usually comprised in an amount of 100,000 parts by weight or less, preferably 10,000 parts by weight or less, and more preferably 5,000 parts by weight or less, with respect to 100 parts by weight of the material for the functional layer.

After the preparation of the liquid composition for forming the functional layer, the liquid composition is applied onto a predetermined area where the functional layer is intended to be formed. Usually, the liquid composition is applied onto a layer (usually, the first electrode, the second electrode, or the active layer) to be in contact with the functional layer in the organic photovoltaic cell of the present invention. Examples of the coating method of the liquid composition may include coating methods similar to the coating methods of the liquid composition for forming the active layer.

The liquid composition for forming the functional layer is applied to form a film comprising the material for the functional layer. Thus, after the application of the liquid composition, as necessary, a process such as a process of drying the formed film to remove the solvent is performed, and consequently the functional layer is obtained.

[8. Other Layer]

The organic photovoltaic cell of the present invention may comprise other layers in addition to the substrate, the first electrode, the second electrode, the active layer, the wavelength conversion layer, the ultraviolet absorbing layer, and the functional layer as long as the effect of the present invention is not significantly impaired.

For example, the organic photovoltaic cell of the present invention may comprise a sealer layer. The sealer layer is a layer that protects the organic photovoltaic cell of the present invention from the outside air, moisture, and the like. Usually, the sealer layer is formed as a layer of a sealer that covers the first electrode, the second electrode, the active layer, the wavelength conversion layer, the ultraviolet absorbing layer, and the functional layer. Hence, the first electrode, the second electrode, the active layer, the wavelength conversion layer, the ultraviolet absorbing layer and the functional layer are usually located in a space formed between the sealer layer and the substrate.

As the sealer, an inorganic sealer may be used and an organic sealer may be used. Examples of the inorganic sealer may include silicon compounds such as silicon oxide, silicon nitride, silicon oxynitride, and silicon carbide; aluminum compounds such as aluminum oxide, aluminium nitride, and aluminum silicate; metal oxides such as zirconium oxide, tantalum oxide, and titanium oxide; metal nitrides such as titanium nitride; and diamond-like carbon. Examples of the organic sealer may include a photocurable resin and a thermosetting resin, and preferred examples include a silicone resin, an epoxy resin, a fluorine resin, and a wax.

The sealers may be used alone or in combination of two or more of them at any ratio.

The thickness of the sealer layer depends on the type of a sealer, but is usually 1 μm or larger, preferably 5 μm or larger, and usually 10 μm or smaller from the viewpoints of protective performance by the sealer layer, the production cost, and the like.

Examples of the method for forming the sealer layer using an inorganic sealer may include a gas phase film formation method such as a chemical vapor deposition method (CVD method) and a physical vapor deposition method (PVD methods) including a sputtering method and a vacuum deposition method. Examples of the method for forming the sealer layer using an organic sealer may include coating methods such as a spin coating method, a dipping method, a spray method; and a method of bonding a previously formed film substance.

The sealer layer may comprise an additive as necessary. Preferred examples of the additive may include a wavelength conversion agent and an ultraviolet absorber. The sealer layer comprising the wavelength conversion agent can serve as the wavelength conversion layer, and consequently the improvement of the photovoltaic conversion efficiency and longer lifetime can be expected. The sealer layer comprising the ultraviolet absorber can serve as the ultraviolet absorbing layer, and consequently longer lifetime can be expected. In particular, when a layer is formed as a layer serving as both the sealer layer and the wavelength conversion layer, the number of layers can be reduced as well as the number of production processes of the organic photovoltaic cell can be reduced, and consequently the cost reduction can be expected.

[9. Embodiments]

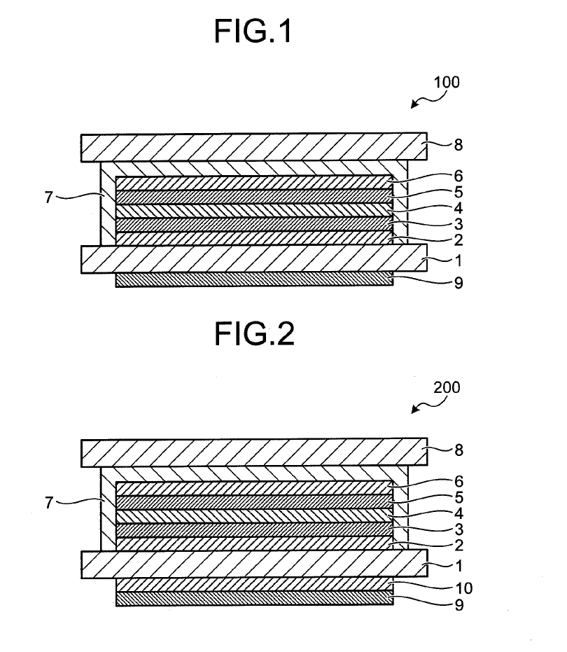

Hereinafter, preferred embodiments of the organic photovoltaic cell of the present invention will be described with reference to drawings. Each of FIG. 1 to FIG. 4 is a schematic cross-sectional view of the organic photovoltaic cell of the embodiment of the present invention. In the below embodiments, the organic photovoltaic cell will be described while the substrate is placed horizontally.

[9-1. First Embodiment]

An organic photovoltaic cell 100 illustrated in FIG. 1 comprises, on a substrate 1, a second electrode 2 serving as the cathode, a functional layer 3 serving as the hole transport layer, an active layer 4 capable of generating a charge by the input of visible light, a functional layer 5 serving as the electron transport layer, and a first electrode 6 serving as the anode in this order. Each of the first electrode 6 and the second electrode 2 is connected with a terminal not illustrated in the schematic for extracting electricity to the exterior. The second electrode 2, the functional layer 3, the active layer 4, the functional layer 5, and the first electrode 6 are covered with a sealer layer 7 except for the terminals to be sealed, and on the sealer layer 7, a substrate 8 is provided. Beneath the substrate 1, a wavelength conversion layer 9 is provided so as to convert wavelength of the input ultraviolet light into visible light having longer wavelength and then output the visible light. Thus, the organic photovoltaic cell 100 comprises the substrate 8, the sealer layer 7, the first electrode 6, the functional layer 5, the active layer 4, the functional layer 3, the second electrode 2, the substrate 1, and the wavelength conversion layer 9 in this order.

The organic photovoltaic cell 100 has the structure as mentioned above. Hence, when light is applied from below in the drawing, visible light among the applied light passes through the wavelength conversion layer 9, the substrate 1, the second electrode 2, and the functional layer 3 to be input to the active layer 4, and charges are generated in the active layer 4. Furthermore, in the organic photovoltaic cell 100 of the present embodiment, ultraviolet light in the applied light is subjected to wavelength-conversion into visible light in the wavelength conversion layer 9. The visible light passes through the substrate 1, the second electrode 2, and the functional layer 3 to be input in the active layer 4, thus generating charges, similarly. Among the charges generated in the active layer 4, holes are transported through the functional layer 3 to the second electrode 2, while electrons are transported through the functional layer 5 to the first electrode 6, and each is extracted through the terminal to the exterior.

As described above, the organic photovoltaic cell 100 effectively uses the applied ultraviolet light energy in the active layer 4 for the charge generation, and therefore can increase light contributing to the photovoltaic conversion to improve the photovoltaic conversion efficiency.

Furthermore, the organic photovoltaic cell 100 can reduce the amount of ultraviolet light input to the active layer 4 as much as that of the ultraviolet light that is subjected to wavelength-conversion. Therefore, the deterioration of the active layer 4 due to the ultraviolet light can be suppressed to elongate the lifetime of the organic photovoltaic cell 100.

The organic photovoltaic cell 100 of the present embodiment is an example that the electrode near the wavelength conversion layer 9 is the cathode and the electrode distant from the wavelength conversion layer 9 is the anode. However, even when the electrode near the wavelength conversion layer 9 is the anode and the electrode distant from the wavelength conversion layer 9 is the cathode, conversely, the same effect can be obtained.

[9-2. Second Embodiment]

An organic photovoltaic cell 200 illustrated in FIG. 2 comprises an ultraviolet absorbing layer 10 between the substrate 1 and the wavelength conversion layer 9 in the organic photovoltaic cell 100. Thus, the organic photovoltaic cell 200 comprises the substrate 8, the sealer layer 7, the first electrode 6, the functional layer 5, the active layer 4, the functional layer 3, the second electrode 2, the substrate 1, the ultraviolet absorbing layer 10, and the wavelength conversion layer 9 in this order.

The organic photovoltaic cell 200 has the structure as mentioned above. Hence, when light is applied from below in the drawing, in a similar manner to that in the first embodiment, visible light in the applied light and visible light that is generated from ultraviolet light by wavelength-conversion in the wavelength conversion layer 9 are input to the active layer 4, thus generating charges in the active layer 4. The charges are extracted from the first electrode 6 and the second electrode 2 through the terminals to the exterior.

Furthermore, in the organic photovoltaic cell 200 of the present embodiment, the ultraviolet light that is not wavelength-converted in the wavelength conversion layer 9 to travel upward in the drawing can be blocked by the ultraviolet absorbing layer 10.

As described above, the organic photovoltaic cell 200 can improve the photovoltaic conversion efficiency in a similar manner to that in the organic photovoltaic cell 100 of the first embodiment. The organic photovoltaic cell 200 can also suppress the input of ultraviolet light to the active layer 4 as much as the ultraviolet light that is blocked by the ultraviolet absorbing layer 10 in addition to the ultraviolet light that is wavelength-converted in the wavelength conversion layer 9. Therefore, the deterioration of the active layer 4 due to the ultraviolet light can be further suppressed than the organic photovoltaic cell 100 of the first embodiment to further elongate the lifetime of the organic photovoltaic cell 200.

The organic photovoltaic cell 200 of the present embodiment is an example that the electrode near the wavelength conversion layer 9 is the cathode and the electrode distant from the wavelength conversion layer 9 is the anode. However, even when the electrode near the wavelength conversion layer 9 is the anode and the electrode distant from the wavelength conversion layer 9 is the cathode, conversely, the same effect can be obtained.

### [9-3. Third Embodiment]

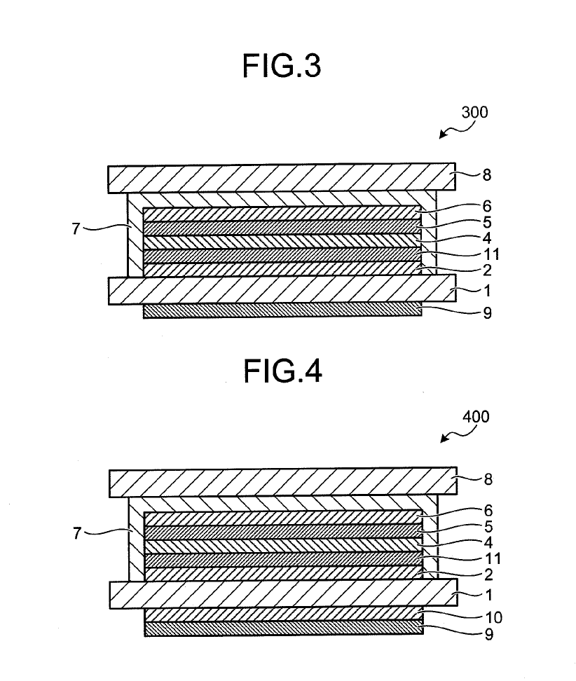

An organic photovoltaic cell 300 illustrated in FIG. 3 comprises, on a substrate 1, a second electrode 2 serving as the anode, a functional layer 11 comprising an ultraviolet absorber and serving as the electron transport layer, an active layer 4 capable of generating a charge by the input of visible light, a functional layer 5 serving as the hole transport layer, and a first electrode 6 serving as the cathode in this order. Each of the first electrode 6 and the second electrode 2 is connected with a terminal not illustrated in the schematic for extracting electricity to the exterior. The second electrode 2, the functional layer 11, the active layer 4, the functional layer 5, and the first electrode 6 are covered with a sealer layer 7 except for the terminals to be sealed, and on the sealer layer 7, a substrate 8 is provided. Beneath the substrate 1, a wavelength conversion layer 9 is provided so as to convert wavelength of the input ultraviolet light into visible light having longer wavelength and then output the light. Thus, the organic photovoltaic cell 300 comprises the substrate 8, the sealer layer 7, the first electrode 6, the functional layer 5, the active layer 4, the functional layer 11, the second electrode 2, the substrate 1, and the wavelength conversion layer 9 in this order.

The organic photovoltaic cell 300 has the structure as mentioned above. Hence, when light is applied from below in the drawing, in a similar manner to that in the first embodiment, visible light in the applied light and visible light that is generated from ultraviolet light by wavelength-conversion in the wavelength conversion layer 9 are input to the active layer 4, and charges are generated in the active layer 4 to be extracted from the first electrode 6 and the second electrode 2 through the terminals to the exterior.

Furthermore, in the organic photovoltaic cell 300 of the present embodiment, the ultraviolet light that is not wavelength-converted in the wavelength conversion layer 9 to travel upward in the drawing can be blocked by the functional layer 11 containing an ultraviolet absorber.

As described above, the organic photovoltaic cell 300 can improve the photovoltaic conversion efficiency in a similar manner to that in the organic photovoltaic cell 100 of the first embodiment. The organic photovoltaic cell 300 can also suppress the input of ultraviolet light to the active layer 4 as much as the ultraviolet light that is blocked by the functional layer 11 in addition to the ultraviolet light that is subjected to wavelength-conversion in the wavelength conversion layer 9. Therefore, the deterioration of the active layer 4 due to ultraviolet light can be further suppressed than the organic photovoltaic cell 100 of the first embodiment to further elongate the lifetime of the organic photovoltaic cell 300.

The organic photovoltaic cell 300 of the present embodiment as example that the electrode near the wavelength conversion layer 9 is the anode and the electrode distant from the wavelength conversion layer 9 is the cathode. However, even when the electrode near the wavelength conversion layer 9 is the cathode and the electrode distant from the wavelength conversion layer 9 is the anode, conversely, the same effect can be obtained.

### [9-4. Fourth Embodiment]

An organic photovoltaic cell 400 illustrated in FIG. 4 comprises an ultraviolet absorbing layer 10 between the substrate 1 and the wavelength conversion layer 9 in the organic photovoltaic cell 300. Thus, the organic photovoltaic cell 400 comprises the substrate 8, the sealer layer 7, the first electrode 6, the functional layer 5, the active layer 4, the functional layer 11, the second electrode 2, the substrate 1, the ultraviolet absorbing layer 10, and the wavelength conversion layer 9 in this order.

The organic photovoltaic cell 400 has the structure as mentioned above. Hence, when light is applied from below in the drawing, in a similar manner to that in the first embodiment, visible light in the applied light and visible light that is generated from ultraviolet light by wavelength-conversion in the wavelength conversion layer 9 are input to the active layer 4, thus generating charges in the active layer 4. The charges are extracted from the first electrode 6 and the second electrode 2 through the terminals to the exterior.

Furthermore, in the organic photovoltaic cell 400 of the present embodiment, the ultraviolet light that is not wavelength-converted in the wavelength conversion layer 9 to travel upward in the drawing can be blocked by the ultraviolet absorbing layer 10 and the functional layer 11 comprising an ultraviolet absorber.

As described above, the organic photovoltaic cell 400 can improve the photovoltaic conversion efficiency in a similar manner to that in the organic photovoltaic cell 100 of the first embodiment. The organic photovoltaic cell 400 can also suppress the input of ultraviolet light into the active layer 4 as much as the ultraviolet light that is blocked by the ultraviolet absorbing layer 10 and the functional layer 11 in addition to the ultraviolet light that is wavelength-converted in the wavelength conversion layer 9. Therefore, the deterioration of the active layer 4 due to ultraviolet light can be further suppressed than the organic photovoltaic cells 100, 200, and 300 of the first to third embodiments to further elongate the lifetime of the organic photovoltaic cell 400.

The organic photovoltaic cell 400 of the present embodiment an example that the electrode near the wavelength conversion layer 9 is the anode and the electrode distant from the wavelength conversion layer 9 is the cathode. However, even when the electrode near the wavelength conversion layer 9 is the cathode and the electrode distant from the wavelength conversion layer 9 is the anode, conversely, the same effect can be obtained.

### [10. Application of Organic Photovoltaic Cell]

In the manner described above, photoelectromotive force is generated between the electrodes of the organic photovoltaic cell of the present invention by the irradiation of light such as sunlight. The organic photovoltaic cell of the present invention may be used, for example, as a solar cell using the photoelectromotive force. When the organic photovoltaic cell is used as the solar cell, the organic photovoltaic cell of the present invention is usually used as the solar cell for an organic thin film solar cell. The plurality of solar cells may also be integrated to make a solar cell module (organic thin film solar cell module) to be used as the solar cell module. The organic photovoltaic cell of the present invention has excellent photovoltaic conversion efficiency and long lifetime as described above; therefore, a solar cell comprising the organic photovoltaic cell of the present invention can be expected to have improved power generation efficiency and longer lifetime.

The organic photovoltaic cell of the present invention may also be used as an organic optical sensor. For example, when the organic photovoltaic cell of the present invention is irradiated with light while applying electrical voltage between the electrodes or without the application, a charge is generated. Hence, when the charge is detected as a photocurrent, the organic photovoltaic cell of the present invention can serve as the organic optical sensor. The plurality of organic optical sensors may be integrated to be used as an organic image sensor.

### [11. Solar Cell Module]

When the organic photovoltaic cell of the present invention is used as the solar cell to constitute the solar cell module, the solar cell module may basically have a module structure similar to that of a conventional solar cell module. The solar cell module generally comprises a supporting substrate, such as a metal and ceramics, on which a solar cell is provided. The solar cell is covered with a filling resin, a protection glass, and the like. Hence, the solar cell can take in light through the side opposite to the supporting substrate. The solar cell module may use a transparent material such as a tempered glass as the supporting substrate, on which the solar cell is provided for taking in light through the transparent supporting substrate.

Known examples of the structure of the solar cell module may include module structures such as a superstraight type, a substrate type, and a potting type; and a substrate-integrated module structure used in an amorphous silicon solar cell. The solar cell module using the organic photovoltaic cell of the present invention may appropriately select a suitable module structure depending on an intended purpose, place, environment, and the like.

For example, in the solar cell modules of the superstraight type and the substrate type as typical module structures, the solar cells are arranged at certain intervals between a pair of supporting substrates. One or both of the supporting substrates are transparent and are usually subjected to an anti-reflective treatment. The adjacent solar cells are electrically connected to each other through wiring such as a metal lead and a flexible wire, and an integrated electrode is placed at a periphery of the solar cell module for extracting electric power generated in the solar cell to the exterior.

Between the supporting substrate and the solar cell, a layer of a filler material such as a plastic material including ethylene vinyl acetate (EVA) may be provided as necessary in order to protect the solar cell and to improve the electric current collecting efficiency. The filler material may be previously formed into a film-shape for installing, or a resin may be filled at a desired position and then cured.

When the solar cell module is used at a place where a hard material is not needed for covering the surface, for example, at a place unlikely to suffer from impact from outside, one of the supporting substrate may not be provided. However, the surface without the supporting substrate of the solar cell module preferably has a surface protection layer by, for example, being covered with a transparent plastic film or being covered with a filler resin to be cured for imparting a protection function.

The periphery of the supporting substrate is usually fixed with a metal frame while interposing the solar cell module in order to seal the inside and to secure rigidity of the solar cell module. A space between the supporting substrate and the frame is usually sealed with a sealing material.

The solar cell module can be used while utilizing the advantages of the organic photovoltaic cell because the solar cell module comprises the organic photovoltaic cell of the present invention that is a photovoltaic cell using an organic material. For example, the organic photovoltaic cell can be formed as a flexible cell, and thus when flexible materials are used for the supporting substrate, the filler material, the sealing material, and the like, a solar cell module can be provided on a curved surface.

The organic photovoltaic cell can be produced using a coating method at low cost, and hence the solar cell module can also be produced using the coating method. For example, when a solar cell module is produced using a flexible support such as a polymer film as the supporting substrate, a solar cell is sequentially formed using the coating method and the like while feeding the flexible support from a roll flexible support, the flexible support is cut into a desired size, and a peripheral part of the cut out piece is sealed with a flexible and moisture-proof material to produce a body of the solar cell module. For example, a solar cell module having a module structure so-called “SCAF” described in “Solar Energy Materials and Solar Cells, 48, p 383-391” can also be obtained.

The solar cell module using the flexible support may also be bonded and fixed to a curved surface glass and the like to be used.

### EXAMPLES

Hereinafter, the present invention will be specifically described with reference to examples, but the present invention is not limited to the examples described below, and any changes and modifications may be made in the present invention without departing from the gist of the present invention.

[Evaluation Method]

In Examples and Comparative Examples described below, a square organic photovoltaic cell having a size of 2 mm×2 mm was produced. For the produced organic photovoltaic cell, using CEP-2000 spectral response measurement system manufactured by Bunkoukeiki Co., Ltd., DC voltage application with respect to the cell was swept at a constant rate of 20 mV/second to determine a short circuit current, an open end voltage, and a fill factor (hereinafter, appropriately abbreviated as “FF”), and the determined short circuit current was multiplied by the determined open end voltage and by the determined fill factor to calculate the photovoltaic conversion efficiency.

The produced organic photovoltaic cell was irradiated with sunlight out of doors for 6 hours for an atmospheric exposure test. In the atmospheric exposure test, sunlight was input from the glass substrate side formed with an ITO film to the active layer. After the atmospheric exposure test, the photovoltaic conversion efficiency was determined, and the photovoltaic conversion efficiency was divided by the photovoltaic conversion efficiency immediately after the production of the organic photovoltaic cell to calculate a photovoltaic conversion efficiency retention. The short circuit current immediately after the production of the organic photovoltaic cell was divided by an area of the active layer to determine an initial short circuit current density, and the short circuit current after the atmospheric exposure test was divided by an area of the active layer to determine a short circuit current density after the atmospheric exposure test.

### Example 1

A glass substrate to which an ITO film having a thickness of 150 nm was attached by a sputtering method as an anode (second electrode) was prepared.

Onto the ITO film, a dispersion liquid (manufactured by Catalysts & Chemicals Ind. Co., Ltd., trade name: titania sol HPW-10R) dispersing titanium dioxide particles and a dispersant was applied by a spin coating method, and dried at room temperature to form a functional layer (electron transport layer) having a thickness of 70 nm. Here, in the dispersion liquid, the titanium dioxide particles had a diameter of 8 nm to 13 nm, the titanium dioxide had an electrical conductivity of 24.6 mS/cm, the solvent in the dispersion liquid was water, and the dispersion liquid had a pH of 1.3. The titanium dioxide was an ultraviolet absorber capable of absorbing light having a wavelength of 411 nm or smaller.

Next, an ortho-dichlorobenzene solution comprising a macromolecular compound A that was an alternating polymer of the monomer represented by Formula (3) and the monomer represented by Formula (4) and [6,6]-phenyl-C₆₁-butyric acid methyl ester (hereinafter, appropriately abbreviated as “[6,6]-PCBM”) at a weight ratio of 1:3 was prepared. The macromolecular compound A was 1% by weight with respect to ortho-dichlorobenzene. Then, the solution was filtered with a filter having a pore size of 0.5 μm. The obtained filtrate was applied onto the functional layer by spin coating and then dried in an N₂ atmosphere. Hence, an active layer having a thickness of 100 nm was obtained. The macromolecular compound A had the weight-average molecular weight of 17,000 in terms of polystyrene and had the number-average molecular weight of 5,000 in terms of polystyrene. The macromolecular compound A had an optical absorption edge wavelength of 925 nm.

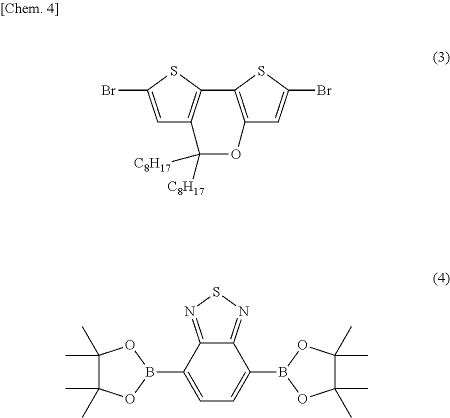

Next, an HIL691 solution (manufactured by Plextronics, trade name: Plexcore HIL691) was applied onto the active layer by a spin coating method to form a functional layer (hole transport layer) having a film thickness of about 50 nm.

Then, Au was deposited as the cathode (first electrode) with a vacuum deposition equipment so as to have a thickness of 100 nm.

Furthermore, onto the cathode, a glass substrate was bonded with an epoxy resin (rapid setting type Araldite) as the sealer for sealing treatment.

Then, onto the surface of the glass substrate with the ITO film opposite to the side on which the ITO film was attached, a coating agent for blocking ultraviolet light (trade name: UV-G13) that was manufactured by Nippon Shokubai Co., Ltd. and that could block ultraviolet light having a wavelength of 380 nm or smaller was applied to form an ultraviolet absorbing layer having a thickness of 6 μm.

Onto the surface of the ultraviolet absorbing layer, a dispersion liquid dispersing an inorganic phosphor Y₃Al₅O₁₂:Ce³⁺ as the wavelength conversion agent in ethanol was applied to form a wavelength conversion layer having a thickness of 100 μm. In the dispersion liquid, the concentration of the inorganic phosphor was 10 g/liter.

As described above, an organic photovoltaic cell comprising the glass substrate, the sealer layer, the cathode as the first electrode, the functional layer, the active layer, the functional layer comprising the ultraviolet absorber, the anode as the second electrode, the glass substrate, the ultraviolet absorbing layer, and the wavelength conversion layer in this order was obtained.

### Comparative Example 1

An organic photovoltaic cell was obtained in the same manner as in Example 1 except that the wavelength conversion layer and the ultraviolet absorbing layer were not formed.

TABLE 1

| | | Comparative |
|---|---|---|
| | Example 1 | Example 1 |
| Photovoltaic conversion | 92.95 | 65.61 |
| efficiency retention [%] | | |

TABLE 2

| | | Comparative |
|---|---|---|
| | Example 1 | Example 1 |
| Initial short circuit | 9.82 | 9.10 |
| current density [mA/cm²] | | |
| Short circuit current density | 9.23 | 7.10 |
| after atmospheric exposure | | |
| test [mA/cm²] | | |

### Example 2

An organic photovoltaic cell was obtained in the same manner as in Example 1 except that the active layer was formed in the manner described below.

The active layer was formed as follows. First, an ortho-dichlorobenzene solution comprising poly(3-hexylthiophene) (hereinafter, appropriately abbreviated as “P3HT”) and [6,6]-PCBM at a weight ratio of 1:0.8 was prepared. P3HT was 1% by weight with respect to ortho-dichlorobenzene. Then, the solution was filtered with a filter having a pore size of 0.5 μm. The obtained filtrate was applied onto the functional layer (electron transport layer) by spin coating and then dried in an N₂ atmosphere at 150° C. for 3 minutes. Hence, an active layer having a thickness of 100 nm was obtained.

### Comparative Example 2

An organic photovoltaic cell was obtained in the same manner as in Example 2 except that the wavelength conversion layer and the ultraviolet absorbing layer were not formed.

TABLE 3

| | | Comparative |
|---|---|---|
| | Example 2 | Example 2 |
| Photovoltaic conversion | 83.43 | 34.37 |
| efficiency retention [%] | | |

TABLE 4

| | | Comparative |
|---|---|---|
| | Example 2 | Example 2 |
| Initial short circuit | 3.09 | 2.67 |
| current density [mA/cm²] | | |
| Short circuit current density | 2.20 | 1.36 |
| after atmospheric exposure | | |
| test [mA/cm²] | | |

### Example 3

An organic photovoltaic cell was obtained in the same manner as in Example 1 except that the ultraviolet absorbing layer was not formed. The photovoltaic conversion efficiency retention was 58.56%.

### Example 4

An organic photovoltaic cell was obtained in the same manner as in Example 2 except that the ultraviolet absorbing layer was not formed. The photovoltaic conversion efficiency retention was 54.99%.

[Evaluation Result]

Each organic photovoltaic cell produced in Examples 1 to 4 was able to suppress the reduction of the photovoltaic conversion efficiency retention with time during the atmospheric exposure test as compared with each organic photovoltaic cell produced in Comparative Example 1 and Comparative Example 2. Namely, each organic photovoltaic cell of Examples 1 to 4 had longer lifetime than that of each organic photovoltaic cell of Comparative Example 1 and Comparative Example 2. Each organic photovoltaic cell of Example 1 and Example 2 had higher photovoltaic conversion efficiency retention than those of Example 3 and Example 4. Each organic photovoltaic cell of Example 1 and Example 2 had higher short circuit current density than those of Comparative Example 1 and Comparative Example 2.

### INDUSTRIAL APPLICABILITY

The organic photovoltaic cell of the present invention can be used as, for example, a solar cell and a photosensor.

1. An organic photovoltaic cell comprising:
a first electrode;
an active layer capable of generating a charge by incident light;
a second electrode; and
a wavelength conversion layer capable of wavelength conversion of incident ultraviolet light into light having longer wavelength than that of the ultraviolet light and outputting the resulting light, in this order.

2. The organic photovoltaic cell according to claim 1, further comprising an ultraviolet absorbing layer between the second electrode and the wavelength conversion layer.

3. The organic photovoltaic cell according to claim 1, further comprising a functional layer between the active layer and the second electrode, the functional layer capable of transporting the charge generated in the active layer to the second electrode, and the functional layer comprising a material capable of absorbing ultraviolet light.

4. The organic photovoltaic cell according to claim 2, further comprising a functional layer between the active layer and the second electrode, the functional layer capable of transporting the charge generated in the active layer to the second electrode, and the functional layer comprising a material capable of absorbing ultraviolet light.

5. The organic photovoltaic cell according to claim 1, wherein the wavelength conversion layer is formed through a process of applying a liquid composition comprising a wavelength conversion agent onto a layer to be in contact with the wavelength conversion layer in the organic photovoltaic cell, and the wavelength conversion agent is capable of wavelength conversion of incident ultraviolet light into light having longer wavelength than that of the ultraviolet light and outputting the resulting light.

6. The organic photovoltaic cell according to claim 1, wherein the wavelength conversion layer comprises an inorganic phosphor.

7. An organic photovoltaic cell comprising:
a first electrode;
an active layer capable of generating a charge by incident light;
a second electrode;
an ultraviolet absorbing layer; and
a wavelength conversion layer capable of wavelength conversion of incident ultraviolet light into light having longer wavelength than that of the ultraviolet light and outputting the resulting light, in this order,
wherein the ultraviolet absorbing layer is formed through a process of applying a liquid composition comprising a material capable of absorbing ultraviolet light onto a layer to be in contact with the ultraviolet absorbing layer in the organic photovoltaic cell.
